(19) United States
(12) Patent Application Publication
(10) Pub. No.: US 2021/0404052 A1
(43) Pub. Date: Dec. 30, 2021

(54) HARD COATING FOR CUTTING TOOL

(71) Applicant: KORLOY INC., Seoul (KR)

(72) Inventors: Je-hun PARK, Cheongju-si (KR); Jin-han GWON, Cheongju-si (KR); Seung-su AHN, Cheongju-si (KR)

(21) Appl. No.: 17/289,883

(22) PCT Filed: Nov. 21, 2019
(86) PCT No.: PCT/KR2019/016023

§ 371 Date: Apr. 29, 2021

(30) Foreign Application Priority Data
Nov. 30, 2018 (KR) 10-2018-0151793

(51) Int. Cl. C23C 14/35; C23C 14/06; C23C 14/08; C23C 28/04; C23C 28/00; B23B 27/14

(52) U.S. Cl. CPC C23C 14/35; C23C 14/0641; C23C 14/081; B23B 2224/04; C23C 28/42; C23C 28/44; B23B 27/14; C23C 28/044

(57) ABSTRACT

A hard coating for cutting tools according to the present invention is a hard coating for cutting tools which is formed on and adjacent to a hard base material by a PVD method, and is characterized in that the thickness of the entire hard coating is 0.5 to 10 μm, and the hard coating includes one or more nitride layers and one or more oxide layers. Each of the one or more nitride layers has a thickness of 0.1 to 5.0 μm and is composed of AlₐTi_{b}Me_{c}N (wherein Me is at least one selected from Si, W, Nb, Mo, Ta, Hf, Zr, and Y, and 0.55≤a≤0.7, 0.2<b≤0.45, and 0≤c<0.1) or AlₐCr_{b}Me_{c}N (wherein Me is at least one selected from Si, W, Nb, Mo, Ta, Hf, Zr, and Y, and 0.55≤a≤0.7, 0.2<b≤0.45, and 0≤c<0.1) in a cubic phase, and each of the one or more oxide layers has a thickness of 0.1 to 3.0 μm and is composed of γ-Al₂O₃ in a cubic phase. When the number of compositionally discontinuous interfaces throughout the hard coating including the hard base material is n, the n satisfies 4≤n≤9, and the ratio of the microhardness (H1) of the nitride layer to the microhardness (H2) of the oxide layer satisfies 1.03<H1/H2<1.3, and the ratio of the elastic modulus of the nitride layer (E1) to the elastic modulus of the oxide layer (E2) satisfies 1.1<E1/E2<1.3. Each of the nitride layers and each of the oxide layers have an elastic deformation resistance index (H/E) of 0.07 to 0.09 and a plastic deformation resistance index (H³/E²) of 0.13 to 0.29, and the elastic deformation resistance index (H/E) of the entire hard coating is 0.09 to 0.12, and the plastic deformation resistance index (H³/E²) of the entire hard coating is 0.29 to 0.32.

### TECHNICAL FIELD

The present invention relates to a hard coating for cutting tools which is formed by a PVD method, and to a coating having excellent bonding force, wear resistance, and chipping resistance.

### BACKGROUND ART

In order to develop a high-hardness cutting tool material, various TiN-based multi-layered film systems have been proposed since the late 1980s.

For example, when coating is performed to form a so-called superlattice having one lattice constant by forming a multi-layered film through repeatedly stacking TiN or VN in an alternate manner to a thickness of several nanometers so that a coherent interface is formed between films despite the difference in lattice constant between individual single layers, the multi-layered film may have a high hardness which is at least two times the typical hardness of each single film. Thus, various attempts have been made to apply the above phenomenon to a thin film for cutting tools.

Recently, a hard coating for cutting tools having various multi-layered structures has been used, which achieves much more improved physical properties than a single film by repeatedly staking nitrides of various compositions such as AlTiN, TiAlN, AlTiMeN (wherein, Me is a metal element) in an alternate manner.

In addition, as in the following patent document, there has also been an attempt to take advantages of each of a nitride and an oxide by compositely stacking Al₂O₃ and a nitride film such as TiAlN.

However, a hard coating, which includes a composite layer of a TiAlN-based nitride film and an Al₂O₃-based oxide film formed by a PVD method, has a low bonding force between respective layers, and a composite multilayer, which is obtained by the complexation of a nitride film having high hardness and elastic modulus and an oxide film having low hardness and elastic modulus, exhibits a hardness and an elastic modulus of median values according to the rule of mixture, and thus does not have excellent wear resistance and chipping resistance. Therefore, there is a problem in that such a composite multilayer is not high in use value as a hard coating for a cutting tool.

### DISCLOSURE OF THE INVENTION

### Technical Problem

An object of the present invention is to provide a hard coating for cutting tools, wherein the hard coating has excellent bonding force between layers constituting the hard coating, and also has excellent wear resistance and chipping resistance.

### Technical Solution

In order to achieve the above object, the present invention provides a hard coating for cutting tools which is formed on and adjacent to a hard base material by a PVD method, wherein the thickness of the entire hard coating is 0.5 to 10 μm, and the hard coating includes one or more nitride layers and one or more oxide layers. Each of the one or more nitride layers has a thickness of 0.1 to 5.0 μm and is composed of AlₐTi_{b}Me_{c}N (wherein Me is at least one selected from Si, W, Nb, Mo, Ta, Hf, Zr, and Y, and 0.55≤a≤0.7, 0.2<b≤0.45, and 0≤c<0.1) or AlₐCr_{b}Me_{c}N (wherein Me is at least one selected from Si, W, Nb, Mo, Ta, Hf, Zr, and Y, and 0.55≤a≤0.7, 0.2<b≤0.45, and 0≤c<0.1) in a cubic phase, and each of the one or more oxide layers has a thickness of 0.1 to 3.0 μm and is composed of γ-Al₂O₃ in a cubic phase. When the number of compositionally discontinuous throughout the hard coating including the hard base material is n, the n satisfies 4≤n≤9, and the ratio of the microhardness (H1) of the nitride layer to the microhardness (H2) of the oxide layer satisfies 1.03<H1/H2<1.3, and the ratio of the elastic modulus of the nitride layer (E1) to the elastic modulus of the oxide layer (E2) satisfies 1.1<E1/E2<1.3. Each of the nitride layers and each of the oxide layers have an elastic deformation resistance index (H/E) of 0.07 to 0.09 and a plastic deformation resistance index (H³/E²) of 0.13 to 0.29, and the elastic deformation resistance index (H/E) of the entire hard coating is 0.09 to 0.12, and the plastic deformation resistance index (H³/E²) of the entire hard coating is 0.29 to 0.32.

### Advantageous Effects

A hard coating according to the present invention has not only excellent bonding force between layers but also excellent wear resistance and chipping resistance over the entirety thereof even in a structure in which a nitride and an oxide are repeatedly stacked, by controlling the composition of each of a nitride layer and an oxide layer constituting the hard coating having a composite multi-layered structure, process conditions, the number of stacked layers, and the like. Accordingly, when the hard coating is applied to a cutting tool, the cutting performance and lifespan of the cutting tool may be improved.

### BRIEF DESCRIPTION OF THE DRAWINGS

FIG. 1 schematically shows the structure of a hard coating according to an embodiment of the present invention.

### MODE FOR CARRYING OUT THE INVENTION

Hereinafter, the configuration and operation of embodiments of the present invention will be described with reference to the accompanying drawings. In the following description of the present invention, when it is determined that detailed descriptions of related known functions or configurations may unnecessarily obscure the gist of the present invention, the detailed descriptions will be omitted. In addition, when a portion is said to “include” any component, it means that the portion may further include other components rather than excluding the other components unless otherwise stated.

As described above, in a hard coating made of a composite layer of a nitride film and an oxide film, there is a significant difference in physical properties such as hardness and elastic modulus between layers due to the difference in composition of each layer, so that there is a limit in securing bonding force between thin films, which is required during a cutting process. In order to solve the above problem, the present inventors have studied and found that an elastic deformation resistance index (H/E) and a plastic deformation resistance index (H³/E²) between thin films affect bonding force between the thin films, and when each thin film has a predetermined range of hardness and elastic modulus, the bonding force, wear resistance, and chipping resistance of the entire hard coating are improved, and have completed the present invention.

A hard coating according to the present invention is formed on a hard base material by a PVD method, wherein the thickness of the entire hard coating is 0.5 to 10 μm, and the hard coating includes one or more nitride layers and one or more oxide layers. Each of the one or more nitride layers has a thickness of 0.1 to 5.0 μm and is composed of AlₐTi_{b}Me_{c}N (wherein Me is at least one selected from Si, W, Nb, Mo, Ta, Hf, Zr, and Y, and 0.55≤a≤0.7, 0.2<b≤0.45, and 0≤c<0.1) or AlₐCr_{b}Me_{c}N (wherein Me is at least one selected from Si, W, Nb, Mo, Ta, Hf, Zr, and Y, and 0.55≤a≤0.7, 0.2<b≤0.45, and 0≤c<0.1) in a cubic phase, and each of the one or more oxide layers has a thickness of 0.1 to 3.0 μm and is composed of γ-Al₂O₃ in a cubic phase. When the number of compositionally discontinuous throughout the hard coating including the hard base material is n, the n satisfies 4≤n≤9, and the ratio of the microhardness (H1) of the nitride layer to the microhardness (H2) of the oxide layer satisfies 1.03<H1/H2<1.3, and the ratio of the elastic modulus of the nitride layer (E1) to the elastic modulus of the oxide layer (E2) satisfies 1.1<E1/E2<1.3. Each of the nitride layers and each of the oxide layers have an elastic deformation resistance index (H/E) of 0.07 to 0.09 and a plastic deformation resistance index (H³/E²) of 0.13 to 0.29, and the elastic deformation resistance index (H/E) of the entire hard coating is 0.09 to 0.12, and the plastic deformation resistance index (H³/E²) of the entire hard coating is 0.29 to 0.32.

In the present invention, the ‘elastic deformation resistance index (H/E)’ means the ratio of a hardness (H) value to an elastic modulus (E) value, and the ‘plastic deformation resistance index (H³/E²)’ means the ratio of the cube of the hardness (H) value to the square of the elastic modulus (E) value.

When the thickness of the entire hard coating is less than 0.5 μm, it is difficult to exhibit thin film's own inherent properties, and when the thickness is greater than 10 μm, the risk of delamination increases when considering that compressive stress accumulated in a thin film is proportional to the thickness of the thin film and the time due to thin film manufacturing characteristics caused by a PVD method. Therefore, it is preferable that the thickness of the entire hard coating is in the range of 0.5 to 1.0 μm, and more preferably, 2 to 8 μm.

When each of the one or more nitride layers has a thickness of less than 0.1 μm, it is difficult to exhibit the wear resistance properties inherently held by a thin film, and when the thickness is greater than 5 μm, the bonding force with an oxide layer is significantly reduced due to an increase in hardness and elastic modulus caused by an increase in compressive stress. Therefore, the thickness of the nitride layer is preferably 0.1 to 5 μm.

In the composition of the one or more nitride layers, when the content of Al is less than 0.55, 1.03<H1/H2<1.3 or 1.1<E1/E2<1.3 is not satisfied, so that the bonding force with an oxide layer is degraded, or 0.09<H/E<0.12 or 0.29<H³/E<0.32 is not satisfied in forming of a composite multilayer with the oxide layer, so that wear resistance and chipping resistance are degraded, resulting in the degradation in value as a cutting tool. In addition, when the content of Al is greater than 0.7, brittleness increases due to the formation of a phase having a hexagonal B4 structure, so that wear resistance is degraded and the lifespan of a tool may be shortened. Therefore, it is preferable that the content of Al is in the range of 0.55 to 0.7.

When each of the one or more oxide layers has a thickness of less than 0.1 μm, it is difficult to exhibit the oxidation resistance properties inherently held by a thin film; and when the thickness if greater than 3 μm, the entire equipment in a coating furnace is subjected to oxidation (poisoning) and becomes insulated, making it no longer possible to deposit an oxide layer. Therefore, the thickness of the oxide layer is preferably 0.1 to 3 μm.

In addition, the oxide layer is preferably made of γ-Al₂O₃ in a cubic phase in order to achieve the hardness, elastic deformation resistance index, and plastic deformation resistance index of the hard coating.

When the number of compositionally discontinuous interfaces throughout the hard coating including the hard base material is n, and when the n is less than 4, the elastic deformation resistance index and the plastic deformation resistance index of a composite multilayer made of a nitride layer and an oxide layer are low (about the median of the high hardness/elastic modulus of the nitride layer and the low hardness/elastic modulus of the oxide layer), so that the wear resistance and chipping resistance of a cutting tool are degraded. When n is greater than 9, the elastic deformation resistance index may increase, but the plastic deformation resistance index decreases, so that the chipping resistance of a cutting tool is degraded. Therefore, it is preferable that the n satisfies 4≤n≤9.

In the hard coating, when the ratio (H1/H2) of the microhardness (H1) of the nitride layer to the microhardness (H2) of the oxide layer is less than 1.03, the bonding force between the nitride layer and the oxide layer is good, but the wear resistance of a cutting tool is degraded due to the low hardness of the nitride layer (based on the hardness of the oxide layer). When the ratio is greater than 1.3, the bonding force between the nitride layer and the oxide layer is greatly degraded, so that each layer is easily torn off during the processing of a cutting tool, causing the tool performance to be greatly degraded. Therefore, it is preferable that the ratio is in the range of 1.03 to 1.3.

In the hard coating, when the ratio (E1/E2) of the microhardness (E1) of the nitride layer to the microhardness (E2) of the oxide layer is less than 1.1, the bonding force between the nitride layer and the oxide layer is good, but the wear resistance of a cutting tool is degraded due to the low elastic modulus of the nitride layer (based on the elastic modulus of the oxide layer). When the ratio is greater than 1.3, the bonding force between the nitride layer and the oxide layer is greatly degraded, so that each layer is easily torn off during the processing of a cutting tool, causing the tool performance to be greatly degraded. Therefore, it is preferable that the ratio is in the range of 1.1 to 1.3.

In the hard coating, when the elastic deformation resistance index (H/E) of each of the nitride layer and the oxide layer is less than 0.07, the elastic modulus (E) is too high compared to the hardness (H), so that the bonding force with the oxide layer is significantly degraded. When H/E is greater than 0.09, the hardness ratio and the elastic modulus ratio limited in the present invention are not satisfied, so that interlayer bonding force is significantly degraded. Therefore, it is preferable that H/E is in the range of 0.07 to 0.09.

In the hard coating, when the plastic deformation resistance index (H³/E²) of each of the nitride layer and the oxide layer is less than 0.13, the elastic modulus (E) is too high compared to the hardness (H), so that the bonding force with the oxide layer is significantly degraded. When H³/E² is greater than 0.29, the hardness ratio and the elastic modulus ratio limited in the present invention are not satisfied, so that interlayer bonding force is significantly degraded. Therefore, it is preferable that H³/E² is in the range of 0.13 to 0.29.

In order to improve the bonding force, the elastic deformation resistance index (H/E) of each of the nitride layer and the oxide layer of each layer constituting the entire hard coating is controlled to be 0.07 to 0.09 and the plastic deformation resistance index (H³/E²) thereof is controlled to be 0.13 to 0.29. However, when a composite multilayer of a nitride layer and an oxide layer is formed as described in the present invention, the entire hard coating exceeds the value of each layer, so that ultimately, wear resistance and chipping resistance are significantly improved. However, when the elastic deformation resistance index of the entire hard coating exceeds 0.12, or the plastic deformation resistance index of the entire hard coating exceeds 0.32, the elastic modulus is too low compared to the hardness, or the hardness is too high compared to the elastic modulus, and therefore the abnormal rapid wear and chipping or premature breakage of a thin film frequently occur during a cutting process, leading to a decrease in the value of a cutting tool.

In the hard coating, the average size of crystal grains constituting the nitride layer and the oxide layer is preferably less than 200 nm.

In the hard coating, it is preferable that the nitride layer and the oxide layer are formed by being alternately and repeatedly stacked.

In the hard coating, the thickness of an oxide layer closest to a base material may be larger than the sum of the thicknesses of the remaining oxide layers.

The hard base material may be a sintered body containing cemented carbide, cermet, high-speed steel, cBN, or diamond.

### EXAMPLES

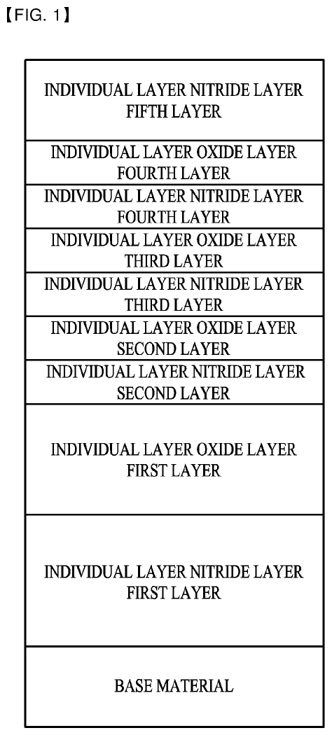

In Examples of the present invention, a bipolar power supply of 40 kHz or higher is applied to the surface of a hard base material made of a sintered body containing cemented carbide, cermet, high-speed steel, cBN, or diamond by using reactive pulse magnetron sputtering, which is physical vapor deposition (PVD) method, and a process temperature of 450 to 600° C. is applied thereto to form a multi-layered film having a structure as shown in FIG. 1.

In the multi-layered film according to the embodiment of the present invention, a nitride layer is formed on the lowermost layer which is in contact with the hard base material, and sequentially, an oxide and a nitride are alternately and repeatedly formed. It is preferable that the number of thin films formed in total is 4 to 9.

Specifically, an arc target of AlTi or AlCr and a sputtering target of Al were used as a target used for coating, the initial vacuum pressure was reduced to 8.5×10⁻⁵ Torr or less, and N₂ and O₂ were injected as a reaction gas. In addition, the gas pressure for coating was maintained at 50 mTorr or less, preferably at 40 mTorr or less, and the coating temperature was 400 to 600° C. A substrate bias voltage applied at the time of coating was −20 V to −100 V for coating a nitride film, and was −100 V to −150 V for coating an oxide film. The above coating conditions may vary depending on equipment characteristics and conditions.

The composition, hardness, elastic modulus, elastic deformation resistance index, and plastic deformation resistance index of each individual layer constituting a composite multilayer are as shown in Tables 1 to 4 below.

TABLE 1

| | Sample No. | 1 | 2 | 3 | 4 | 5 |
|---|---|---|---|---|---|---|
| Individual | AlTi(EDX, at %) | 51:49 | 55:45 | 61:39 | 67:33 | 73:27 |
| layer 1-1 | Hardness (H1) | 31 | 33.0 | 36.1 | 34.5 | 28.5 |
| (Nitride layer) | Elastic modulus (E1) | 382 | 380.5 | 409.9 | 390.2 | 340 |
| | H/E | 0.081 | 0.087 | 0.088 | 0.088 | 0.084 |
| | H³/E² | 0.204 | 0.248 | 0.280 | 0.270 | 0.200 |
| | H1/H2 | 1.069 | 1.138 | 1.245 | 1.190 | 0.983 |
| | E1/E2 | 1.158 | 1.153 | 1.242 | 1.182 | 1.030 |

In Table 1, H1/H2 and E1/E2 are based on values of Individual layer 1-1 and values of Individual layer 2 of Table 4.

TABLE 2

| | Sample No. | 6 | 7 |
|---|---|---|---|
| Individual | AlCrSi(EDX, at %) | 64:36 | 60:35:5 |
| layer 1-2 | Hardness (H1) | 30.5 | 32.7 |
| (Nitride layer) | Elastic modulus (E1) | 380.8 | 397 |
| | H/E | 0.080 | 0.082 |
| | H³/E² | 0.196 | 0.222 |
| | H1/H2 | 1.052 | 1.128 |
| | E1/E2 | 1.154 | 1.203 |

In Table 2, H1/H2 and E1/E2 are based on values of Individual layer 1-2 and values of Individual layer 2 of Table 4.

TABLE 3

| | Sample No. | 8 | 9 |
|---|---|---|---|
| Individual | AlTi(EDX, at %) | 59:39:2 | 50:40:10 |
| layer 1-3 | Hardness (H1) | 36.5 | 43.5 |
| (Nitride layer) | Elastic modulus (E1) | 410 | 440 |
| | H/E | 0.089 | 0.099 |
| | H³/E² | 0.289 | 0.425 |
| | H1/H2 | 1.259 | 1.5 |
| | E1/E2 | 1.242 | 1.333 |

In Table 3, H1/H2 and E1/E2 are based on values of Individual layer 1-3 and values of Individual layer 2 of Table 4.

TABLE 4

| | Sample No. | 10 |
|---|---|---|
| Individual | Al₂O₃(EDX, at %) | 100 |
| layer 2 | Hardness (H2) | 29 |
| Oxide layer | Elastic modulus (E2) | 330 |
| | H/E | 0.088 |
| | H³/E² | 0.224 |
| | H1/H2 | Comparison with Individual |
| | | layers 1-1, 1-2, and 1-3 |
| | E1/E2 | Comparison with Individual |
| | | layers 1-1, 1-2, and 1-3 |

A total of 19 samples were prepared through a structure in which each individual layer having the above-described composition and physical properties was alternately and repeatedly stacked on the surface of a hard base material in a combination as shown in Tables 5 to 8 below.

TABLE 5
Composite multilayer of Individual layer 1-1 and
Individual layer 2 (if Thickness of 1^{st} oxide layer >
Thicknesses of 2^{nd} + 3^{rd} + 4^{th} layers is satisfied)

| | AlTi | Number of | | Elastic | | |
|---|---|---|---|---|---|---|
| Sample | (EDX, | AlTiN/Al₂O₃ | Hardness | modulus | | |
| No. | at %) | multilayers | (H) | (E) | H/E | H³/E² |
| 11 | 51:49 | 3 | 29.5 | 350 | 0.084 | 0.210 |
| 12 | 51:49 | 7 | 30.2 | 360 | 0.084 | 0.213 |
| 13 | 55:45 | 7 | 30.8 | 340.2 | 0.091 | 0.252 |
| 14 | 61:39 | 3 | 29.3 | 350.2 | 0.084 | 0.205 |
| 15 | 61:39 | 7 | 33.5 | 350.8 | 0.095 | 0.306 |
| 16 | 61:39 | 9 | 33.9 | 352.1 | 0.096 | 0.314 |
| 17 | 61:39 | 10 | 32.8 | 350.1 | 0.094 | 0.288 |
| 18 | 67:33 | 7 | 31.5 | 321.2 | 0.098 | 0.303 |
| 19 | 67:33 | 10 | 31.4 | 330 | 0.095 | 0.284 |
| 20 | 73:27 | 3 | 29.1 | 330.3 | 0.088 | 0.226 |
| 21 | 73:27 | 9 | 29.5 | 338.8 | 0.087 | 0.224 |
| 22 | 73:27 | 10 | 29.4 | 340.3 | 0.086 | 0.219 |

TABLE 6
Composite multilayer of Individual layer 1-2 and
Individual layer 2 (if Thickness of 1^{st} oxide layer >
Thicknesses of 2^{nd} + 3^{rd} + 4^{th} layers is satisfied)

| | AlCrSi | Number of | | Elastic | | |
|---|---|---|---|---|---|---|
| Sample | (EDX, | AlTiN/Al₂O₃ | Hardness | modulus | | |
| No. | at %) | multilayers | (H) | (E) | H/E | H³/E² |
| 23 | 64:36 | 7 | 32.1 | 337.1 | 0.095 | 0.291 |
| 24 | 60:35:5 | 7 | 32.6 | 338 | 0.096 | 0.303 |

TABLE 7
Composite multilayer of Individual layer 1-3 and
Individual layer 2 (if Thickness of 1^{st} oxide layer >
Thicknesses of 2^{nd} + 3^{rd} + 4^{th} layers is satisfied)

| | AlTiSi | Number of | | Elastic | | |
|---|---|---|---|---|---|---|
| Sample | (EDX, | AlTiN/Al₂O₃ | Hardness | modulus | | |
| No. | at %) | multilayers | (H) | (E) | H/E | H³/E² |
| 25 | 59:39:2 | 7 | 35.4 | 376.6 | 0.094 | 0.312 |
| 26 | 40:40:10 | 7 | 37.9 | 390.5 | 0.097 | 0.357 |

TABLE 8
Composite multilayer of Individual layer 1-1 and
Individual layer 2 (if Thickness of 1^{st} oxide layer >
Thicknesses of 2^{nd} + 3^{rd} + 4^{th} layers is satisfied)

| | AlTi | Number of | | Elastic | | |
|---|---|---|---|---|---|---|
| Sample | (EDX, | AlTiN/Al₂O₃ | Hardness | modulus | | |
| No. | at %) | multilayers | (H) | (E) | H/E | H³/E² |
| 27 | 61:39 | 7 | 29.8 | 348 | 0.086 | 0.219 |
| 28 | 61:39 | 9 | 30.5 | 355 | 0.086 | 0.225 |
| 29 | 67:33 | 9 | 30.9 | 349 | 0.089 | 0.242 |

As shown in Table 5, in the case of Samples 11 to 22, a composite multilayer was formed by stacking the nitride of Individual layer 1-1 and the oxide of Individual layer 2 to have the structure as shown in FIG. 1, wherein the first oxide layer closest to the hard base material has a thickness larger than the sum of the thicknesses of the remaining oxide layers.

As shown in Table 6, in the case of Samples 23 to 24, a composite multilayer was formed by stacking the nitride of Individual layer 1-2 and the oxide of Individual layer 2 to have the structure as shown in FIG. 1, wherein the first oxide layer closest to the hard base material has a thickness larger than the sum of the thicknesses of the remaining oxide layers.

As shown in Table 7, in the case of Samples 25 to 26, a composite multilayer was formed by stacking the nitride of Individual layer 1-3 and the oxide of Individual layer 2 to have the structure as shown in FIG. 1, wherein the first oxide layer closest to the hard base material has a thickness larger than the sum of the thicknesses of the remaining oxide layers.

As shown in Table 8, in the case of Samples 27 to 28, a composite multilayer was formed by stacking the nitride of Individual layer 1-1 and the oxide of Individual layer 2 to have the structure as shown in FIG. 1, wherein the first oxide layer closest to the hard base material has a thickness not larger than the sum of the thicknesses of the remaining oxide layers.

Evaluation of Physical Properties of Hard Coating

The delamination resistance, wear resistance, and chipping resistance of composite multi-layered films formed to have the characteristics shown in Tables 5 to 8 were evaluated under the following evaluation conditions.

(1) Evaluation of Delamination Resistance: Presence or Absence of Abnormal Wear Due to Tearing of Thin Film

Material to be cut: SM45C

Sample model number: SNMX1206ANN-MM

Cutting speed: 200 m/min

Cutting feed: 0.2 mm/tooth

Cutting depth: 2 mm

(2) Evaluation of Wear Resistance: Wear of Insert Clearance Surface and Inclined Surface

Material to be cut: SCM440

Sample model number: SNMX1206ANN-MM

Cutting speed: 250 m/min

Cutting feed: 0.2 mm/tooth

Cutting depth: 2 mm

(3) Evaluation of Chipping Resistance: Chipping of Nose R Portion and Boundary Portion of Insert Cutting Edge

Material to be cut: STS316L

Sample model number: APMT1604PDSR-MM

Cutting speed: 150 m/min

Cutting feed: 0.2 mm/tooth

Cutting depth: 10 mm

The evaluation results obtained under the above conditions are shown in Table 9 below.

TABLE 9

| | Delamination resistance | | Wear resistance | | Chipping resistance | | |
|---|---|---|---|---|---|---|---|
| | Processing | | Processing | | Processing | | |
| Number | length (mm) | Wear type | length (mm) | Wear type | length (mm) | Wear type | Notes |
| 11 | 660 | Thin film | 2600 | Excessive | 550 | R portion | Comparative |
| | | tearing, | | wear | | chipping | Example |
| | | excessive | | | | | |
| | | wear | | | | | |
| 12 | 640 | Thin film | 4800 | Normal | 200 | Boundary | Comparative |
| | | tearing, | | wear | | portion | Example |
| | | chipping | | | | chipping | |
| 13 | 2200 | Normal | 4800 | Normal | 400 | R portion | Comparative |
| | | wear | | wear | | chipping | Example |
| 14 | 2150 | Normal | 3000 | Excessive | 420 | Boundary | Comparative |
| | | wear | | wear | | portion | Example |
| | | | | | | chipping | |
| 15 | 2450 | Normal | 5200 | Normal | 1600 | Normal | Example |
| | | wear | | wear | | wear | |
| 16 | 2400 | Normal | 5200 | Normal | 1400 | Normal | Example |
| | | wear | | wear | | wear | |
| 17 | 2000 | Normal | 5000 | Normal | 430 | R portion | Comparative |
| | | wear | | wear | | chipping | Example |
| 18 | 2400 | Normal | 5200 | Normal | 200 | Normal | Example |
| | | wear | | wear | | wear | |
| 19 | 2000 | Normal | 5000 | Normal | 400 | Boundary | Comparative |
| | | wear | | wear | | portion | Example |
| | | | | | | chipping | |
| 20 | 600 | Thin film | 1000 | Excessive | 550 | Boundary | Comparative |
| | | tearing, | | wear, | | portion | Example |
| | | chipping | | breakage | | chipping | |
| 21 | 800 | Thin film | 1200 | Excessive | 400 | R portion | Comparative |
| | | tearing, | | wear, | | and | Example |
| | | chipping | | breakage | | boundary | |
| | | | | | | portion | |
| | | | | | | chipping | |
| 22 | 650 | Thin film | 1000 | Excessive | 400 | Boundary | Comparative |
| | | tearing, | | wear, | | portion | Example |
| | | chipping | | breakage | | chipping | |
| 23 | 2200 | Normal | 4800 | Normal | 1400 | Normal | Example |
| | | wear | | wear | | wear | |
| 24 | 2400 | Normal | 4800 | Normal | 1200 | Normal | Example |
| | | wear | | wear | | wear | |
| 25 | 2800 | Normal | 5200 | Normal | 1200 | Normal | Example |
| | | wear | | wear | | wear | |
| 26 | 750 | Thin film | 5400 | Normal | 750 | R portion | Comparative |
| | | tearing, | | wear | | chipping | Example |
| | | chipping | | | | | |
| 27 | 2400 | Normal | 3000 | Excessive | 800 | Boundary | Comparative |
| | | wear | | wear | | portion | Example |
| | | | | | | chipping | |
| 28 | 2100 | Normal | 3400 | Excessive | 620 | Boundary | Comparative |
| | | wear | | wear | | portion | Example |
| | | | | | | chipping | |
| 29 | 2000 | Normal | 3400 | Excessive | 600 | Boundary | Comparative |
| | | wear | | wear | | portion | Example |
| | | | | | | chipping | |

As it can be confirmed in Table 9 above, Samples Nos. 15, 16, 18, 23, 24, and 25 corresponding to Examples are excellent in delamination resistance, wear resistance, and chipping resistance compared to those of Comparative Examples.

On the other hand, Samples Nos. 11, 12, 14, 20, 21, 22, 27, 28, 29 having a small elastic deformation resistance index (H/E) or a small plastic deformation resistance index (H³/E²) are low, and Samples Nos. 11 to 14, 17, 19 to 22, and 26 to 29, and Samples Nos. 27 to 29 in which the thickness of the first oxide layer is formed to be smaller than the thicknesses of the remaining oxide layers, it can be seen that there is a significant difference in delamination resistance, wear resistance, and chipping resistance.

That is, it can be seen that a hard coating having the composition, hardness, and stacking structure according to the present invention is capable of implementing improved delamination resistance, wear resistance, and chipping resistance compared to a typical hard coating in which a nitride layer and an oxide layer are composited.

1. A hard coating for cutting tools which is formed on and adjacent to a hard base material by a PVD method, wherein
the thickness of the entire hard coating is 0.5 to 10 μm;
the hard coating includes one or more nitride layers and one or more oxide layers;
each of the one or more nitride layers has a thickness of 0.1 to 5.0 μm and is composed of AlₐTi_{b}Me_{c}N (wherein Me is at least one selected from Si, W, Nb, Mo, Ta, Hf, Zr, and Y, and 0.55≤a≤0.7, 0.2<b≤0.45, and 0≤c<0.1) or AlₐCr_{b}Me_{c}N(wherein Me is at least one selected from Si, W, Nb, Mo, Ta, Hf, Zr, and Y, and 0.55≤a≤0.7, 0.2<b≤0.45, and 0≤c<0.1) in a cubic phase;
each of the one or more oxide layers has a thickness of 0.1 to 3.0 μm and is composed of γ-Al₂O₃ in a cubic phase;
when the number of compositionally discontinuous interfaces throughout the hard coating including the hard base material is n, the n satisfies 4≤n≤9;
the ratio of the microhardness (H1) of the nitride layer to the microhardness (H2) of the oxide layer satisfies 1.03<H1/H2<1.3, and the ratio of the elastic modulus of the nitride layer (E1) to the elastic modulus of the oxide layer (E2) satisfies 1.1<E1/E2<1.3;
each of the nitride layers and each of the oxide layers have an elastic deformation resistance index (H/E) of 0.07 to 0.09 and a plastic deformation resistance index (H3/E2) of 0.13 to 0.29;
the elastic deformation resistance index (H/E) of the entire hard coating is 0.09 to 0.12; and
the plastic deformation resistance index (H³/E²) of the entire hard coating is 0.29 to 0.32.

2. The hard coating for cutting tools of claim 1, wherein the average crystal grain size of each layer constituting the hard coating is less than 200 nm.

3. The hard coating for cutting tools of claim 1, wherein
the nitride layers and the oxide layers are repeatedly formed in an alternating manner, and
a nitride layer is formed most adjacent to the hard base material.

4. The hard coating for cutting tools of claim 1, wherein the thickness of an oxide layer formed closest to the base material is larger than the sum of the thicknesses of the remaining oxide layers.
